(19) United States
(12) Patent Application Publication
(10) Pub. No.: US 2009/0065954 A1
(43) Pub. Date: Mar. 12, 2009

(54) Packaging Method For Wideband Power Using Transmission Lines

(76) Inventor: Attma Sharma, Colorado Springs, CO (US)

Correspondence Address: Attma Sharma, 5276 Pinon Valley Road, Colorado Springs, CO, 80919, US

(21) Appl. No.: 11/851,438

(22) Filed: Sep. 7, 2007

(51) Int. Cl. H01L 23/52; H01P 1/00

(52) U.S. Cl. 257/784; 333/247; 257/E23.068

(57) ABSTRACT

Embodiments of the invention relate to a package design incorporating an ultra-low characteristic impedance transmission line (T-line) bundle. The T-line bundle can extend from inside the package to outside the package in order to provide power delivery and power interconnect for a chip. In one embodiment, the T-line bundle can be attached at the die. In another embodiment, the T-line bundle can be attached to the package substrate. The T-line bundle can be a stack of parallel planar transmission line strips in a periodic pattern where the dielectric material of the strips can be a high-k dielectric and can be flexible, semi-rigid, or precision rigid.

The subject invention was made with government support under a research project supported by the Center for Power Electronics System, an Engineering Research Center under National Science Foundation Contract #EEC-9731677.

### BACKGROUND OF INVENTION

The subject invention relates generally to semiconductor packaging. More particularly, to package designs for high-speed, high power signal delivery.

Semiconductor packaging is the method of enclosing a chip or discrete device in a package. The package designs must account for the demands of power, load, and current by the chip or device. In particular, package designs for high-speed devices need to address complex thermal, power delivery, and signal integrity requirements.

Various designs have been created to address power delivery to a chip, including location and number of pins, packaging materials, connectors, and decoupling capacitance.

### BRIEF SUMMARY

Embodiments of the invention relate to a package design incorporating an ultra-low characteristic impedance transmission line (T-line) bundle. The T-line bundle can extend from inside the package to outside the package in order to provide power delivery and power interconnect for a chip. In one embodiment, the T-line bundle can be attached at the die. In another embodiment, the T-line bundle can be attached to the package substrate. The T-line bundle can be a stack of parallel planar transmission line strips in a periodic pattern where the dielectric material of the strips can be a high-k dielectric and can be flexible, semi-rigid, or precision rigid.

### BRIEF DESCRIPTION OF DRAWINGS

FIGS. 1A and 1B show two diagrams of embodiments of a packaging scheme in accordance with the subject invention.

### DETAILED DISCLOSURE

Embodiments of the invention pertain to methods and apparatus for high power delivery for electronic packages. Embodiments of the invention relate to a package design incorporating an ultra-low characteristic impedance transmission line (T-line) bundle. The T-line bundle can extend from inside the package to outside the package in order to provide power delivery and power interconnect for a chip. In one embodiment, the T-line bundle can be attached at the die. In another embodiment, the T-line bundle can be attached to the package substrate. The T-line bundle can be a stack of parallel planar transmission line strips in a periodic pattern where the dielectric material of the strips can be a high-k dielectric and can be flexible, semi-rigid, or precision rigid. Embodiments of the subject invention improve power delivery and signal integrity capability by using an improved package design. The package design incorporates power transmission line bundles having ultra-low characteristic impedance for power delivery. The methods and apparatus of the subject invention can be incorporated in a variety of applications, including, but not limited to, microprocessor packages, RF IC packages, semiconductor laser system packaging, and packaging for any high-speed, high power system. A specific embodiment relates to a package design suitable for wideband (high-speed) high power delivery at high load current slew-rates or di/dt's, such as those occurring in microprocessor, RF power and laser applications.

As packaging technology moves towards faster transition speeds and increased number of signal inputs and outputs, it can be beneficial to analyze the circuits using a combination of lumped circuit and distributed circuit theory. Embodiments of the subject invention can incorporate a package power interconnect design designed according to such a dual lumped circuit and distributed circuit theory. Traditionally, power delivery and package power interconnect design incorporates lumped high-density capacitors. In one embodiment, instead of trying to design lumped high-density capacitors, a significant portion of former die and/or embedded substrate capacitors can be “extruded” out to form ultra-low impedance transmission lines that extend from load (inside package) to PCB (outside package).

In a preferred embodiment, the power lines of a package can be designed as ultra-low characteristic impedance (˜milliohms) transmission lines. A preferred power delivery path should maintain low output impedance all the way out to the load over all frequencies. Eventually at high frequencies, the interconnects are treated as transmission lines and preferably have low characteristic impedance, comparable to that of the output impedance of the power supply. Embodiments of the invention can be utilized with distributed circuit applications.

In embodiments, the power lines of a package can form an ultra-low characteristic impedance (ultra-low Z) transmission line bundle. In a specific embodiment, the ultra-low Z transmission line bundle can incorporate a stack of parallel planar transmission line (or T-line) strips in a periodic pattern such as Power-Dielectric-Ground-Dielectric. The T-lines can include a high dielectric constant, flexible material clad in conductors of predetermined resistance per unit length. The transmission line bundle can be, for example, flexible, semi-rigid, or precision rigid.

Accordingly, an embodiment of a power supply line in accordance with the invention can behave as a dispersive T-line with characteristic impedance less than or equal to the desired output resistance of the power supply. Thus, any high di/dt transient at the load end immediately sets up a voltage ripple wave, of no more than the specified voltage deviation, which is dispersed (i.e. edges are slowed down) as it propagates toward the power supply (source). By the time the voltage ripple waves reach the PCB, the current-voltage waves have lower gradients that can make it easier for lumped passive filters (which are plagued by parasitic inductance or esl), feedback controlled active filters (which are band-limited), and power supplies (which are severely band-limited) to maintain voltage regulation.

Alternatively, the T-line bundle can effectively remove the problem of regulating or filtering at the load. In a specific embodiment, the T-line bundle moves the regulating or filtering of the power supply from the load to the PCB where more space can be made available for filter capacitors. In one embodiment, the package can mitigate the effects of PCB level bypass capacitors' parasitic inductance. Since a lossy (dispersive) T-line slows down traveling wave edges, the lower di/dt at the PCB end induces less noise for a given parasitic inductance (esl) of the PCB filter capacitors. In a preferred embodiment, the power supply, including active filter and passive filter, approximately matches the output impedance of the T-line bundle.

In reference to the power interconnects, which are not limited by “total path inductance”, lumped parasitic inductance effects can be mitigated by the transmission line design. During design, cause for concern can occur at structural discontinuities in the interconnect, i.e., at the soldered, clamped or press-fit joints. These structural discontinuities are typically much smaller than the T-line interconnect and may be modeled as a lumped element termination or splice. Even when the discontinuity is inductive, its inductance value will naturally be much smaller than the total inductance associated with the equivalent total inductance of the traditional power pin configuration and layout, causing less voltage deviation for a shorter time. The discontinuity may be made net capacitive through careful design.

In one embodiment, the lines for power delivery and the lines for input and output signals (I/O lines) can be separated from each other using varying materials and/or by design. In a specific embodiment, I/O lines and power lines can be designed separated by geometry. In a further embodiment, the lines for power delivery can be formed differently than the signal I/O (input/output).

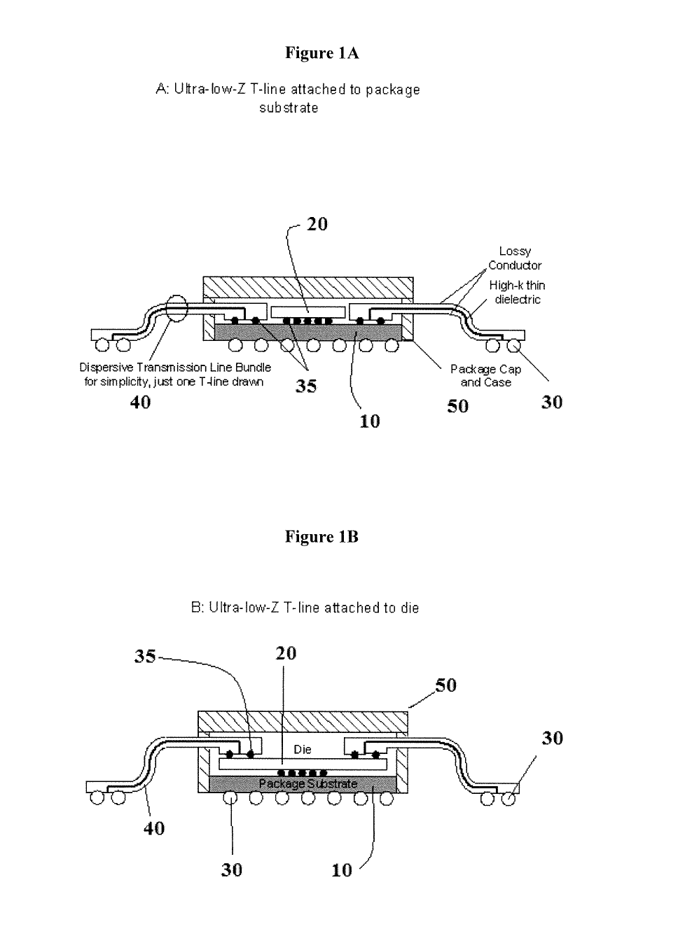

FIGS. 1A and 1B show two embodiments of the subject invention, where FIG. 1A shows an embodiment with an ultra-low transmission line attached to package substrate and FIG. 1B shows an embodiment with an ultra-low-Z transmission line attached to the die. Referring to FIG. 1A, an embodiment of the package design can incorporate a package substrate 10 upon which a chip or die 20 is electrically connected, a package cap and case 50 to protect and enclose the die 20, and package connectors 30 for connecting the package to a PCB or motherboard. The power supply delivery to the die 20 can be accomplished through transmission lines 40 attached to the package substrate 10. In one embodiment, solder microbumps 35 can be used to electrically connect and attach the transmission lines 40 and the die 20 to the package substrate 10. The transmission lines 40 can extend from the package case 50 and connect to the PCB or motherboard by, for example, PCB solder pins in a similar fashion as package connectors 30.

Referring to FIG. 1B, an embodiment of the package design can incorporate a package substrate 10 upon which a chip or die 20 is electrically connected, a package cap and case 50 to protect and enclose the die 20, and package connectors 30 for connecting the package to a PCB or motherboard. The power supply delivery to the die 20 can be accomplished through transmission lines 40 attached to the die 20. In one embodiment, solder microbumps 35 can be used to electrically connect and attach the transmission lines 40 to the die 20, and the die 20 to the package substrate 10. The transmission lines 40 can extend from the package case 50 and connect to the PCB or motherboard by, for example, PCB solder pins in a similar fashion as package connectors 30.

In various embodiments, the overall package design can be similar to the LGA 775 and other Intel packages, but can incorporate the subject power supply lines as transmission line bundles.

In an embodiment, the T-line bundles may be formed by stacking thin laminate strips. The thin laminate strips can be similar to the C-ply laminate strips from 3M and the HiK or PYRALUX laminates from Dupont used for embedding capacitance in PCBs (see Peiffer et al. “Electrical Performance Advantages of Ultra-Thin Dielectric Materials Used for Power-Ground Cores in High Sppeed Multilayer Printed Circuit Boards” IPC Printed Circuits Expo 2003; and Peiffer “Thin PCB Laminates for Power Distribution How Thin is Thin Enough?” TecForum at DesignCon 2002 and U.S. Pat. No. 4,908,258, which are hereby incorporated by reference in their entirety.).

In a further embodiment, multiple T-lines can be stacked using the same lamination technology to form a second substrate, which can then be bonded to the package substrates (FIG. 1A), or bonded to the die (FIG. 1B), using similar (or the same) solder microbump bonding processes. It is known in the art, and can be incorporated in embodiments of the invention, how to make multi-layer substrates (see U.S. Pat. No. 6,992,378 and U.S. Pat. No. 6,961,231), multi-level (double) substrate packages (see U.S. Pat. No. 6,876,553), bended or folded substrates (see U.S. Pat. No. 6,869,825), and precision micro-scale die and substrate layout and bonding (see also U.S. Pat. No. 6,828,666 and Braunisch et al., “Electrical performance of bumpless build-up layer packaging,” Proceedings, Electronic Components and Technology Conference, 2002).

In a specific embodiment, the laminate strips can have a dielectric constant in the range 20-40. In a further embodiment, the laminates can have a thickness of about 8 μm with 10% tolerance, and be clad in 0.5 to 2 oz of copper. Other lamination specifications can also be utilized. In one embodiment, a single T-line strip can be 50 to 100 μm thick.

As an example, using 10 μm C-ply clad in 0.5 oz (35 μm) copper alloy (the alloy elements modify resistivity, and test samples can be in the range 10×10⁻⁸ to 10×10⁶ Ωm), a strip 1 cm wide has 80 mΩ characteristic impedance (using k=20). Therefore, a stacked bundle of 20 T-lines would be approximately 1 mm thick and have between 2-4 mΩ overall impedance depending on the power/ground-return configuration and the level of use of the individual lines. Four of these T-line bundles off the “wings” of the package would in effect bring the overall impedance seen by high frequency components (the components that cannot be regulated by any other means) of the load current to less than 1 mΩ. Hence, a 100 A ideal step load would cause only about 100 mV of ripple. Assuming 100 μm contact pitch (solder contact and insulation space), the total contact footprint at the load end will be 2 mm wide.

Accordingly, embodiments of the subject package may allow for a reduction in die and/or package capacitors. When the power transmission line bundle is attached at the die, die capacitance may be greatly reduced and package capacitance may even be eliminated. When the power T-line is attached to the package substrate (eg. OLGA board of microprocessor) package capacitance may be greatly reduced and die capacitance may be reduced slightly. Depending on the amount of losses tolerable in the T-line, di/dt at the PCB end may even be low enough to reduce PCB (motherboard) capacitors.

Furthermore, embodiments of the subject package can be designed to overcome delays in feedback control. Due to the high dielectric constant and low propagation velocity in the power transmission line relative to the signal transmission line, the sense signal can reach the control circuitry ahead of the actual time that the power supply (or active filter) needs to respond. This feature may be used in the package design to compensate for delays in the feedback and control circuit.

As described above, the present invention can provide one or more of the following advantages:

The parallel strip transmission-line structure can exhibit much lower characteristic impedance than parallel pins/bumps and can significantly lower di/dt noise.

Further, moving the power lines to T-line bundles opens up space for a greater number of signal I/O. In particular, the T-line bundles physically bring the power out to the “wings” of the package, such that the many pins in the base array that would have been used for power delivery can now be allocated to signal lines, therefore allowing expansion of signal I/O while at the same time accommodating the increased power consumption and switching associated with the expansion.

In addition, reliability can be increased because the T-lines can loosen minimum length constraints on the interconnects. The interconnects can be designed as transmission-lines of uniformly low impedance all the way to the die and therefore the physical length and “DC inductance” are not important. Discontinuities associated with transitions from structure to structure, layer to layer, can be made capacitive by design.

Further, overall cost can be lowered by the reduction of package and die capacitance. Specifically, lumped capacitors can be used just at the discontinuities along the power transmission line path and can be designed to only be large enough to overcome parasitic inductance of the discontinuity, rather than the entire interconnect length. The reduction of lumped capacitors occupies less area on the silicon.

All patents, patent applications, provisional applications, and publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

I claim:

1. A semiconductor package, comprising:
a package substrate;
a die electrically connected to the package substrate and enclosed in a package case;
one or more transmission line bundles for power delivery and interconnect to the die, wherein the one or more transmission line bundles extend from inside the package case to outside the package case.

2. The semiconductor package according to claim 1, wherein the one or more transmission line bundles are attached and electrically connected to the die.

3. The semiconductor package according to claim 1, wherein the one or more transmission line bundles are attached and electrically connected to the package substrate.

4. The semiconductor package according to claim 1, wherein the one or more transmission line bundles are ultra-low characteristic impedance transmission line bundles.

5. The semiconductor package according to claim 1, wherein the one or more transmission line bundles comprise a stack of parallel planar transmission line strips in a selected pattern.

6. The semiconductor package according to claim 5, wherein the planar transmission line strips are thin laminate strips having a high dielectric constant.

7. The semiconductor package according to claim 1, wherein the one or more transmission line bundles form a secondary substrate of a stack transmission line bundles.

8. The semiconductor package according to claim 7, wherein the secondary substrate is attached to the die.

9. The semiconductor package according to claim 7, wherein the secondary substrate is attached to the package substrate.
